(19) United States
(12) Patent Application Publication
(10) Pub. No.: US 2009/0219712 A1
(43) Pub. Date: Sep. 3, 2009

(54) CONDUCTING WALLPAPER

(75) Inventors: Conrad Wilhelmus Adriaan Verjans, Landgraaf (NL); Dietrich Bertram, Aachen (DE)

Correspondence Address: Philips Intellectual Property and Standards, P.O. Box 3001, Briarcliff Manor, NY, 10510-8001, US

(73) Assignee: KONINKLIJKE PHILIPS ELECTRONICS N V, Eindhoven (NL)

(21) Appl. No.: 12/299,648

(22) PCT Filed: Apr. 26, 2007
(86) PCT No.: PCT/IB07/51558

§ 371 Date: Nov. 5, 2008

(30) Foreign Application Priority Data
May 9, 2006 (EP) 06113691.7

(51) Int. Cl. F21S 8/00; H05K 1/00; H01R 4/24

(52) U.S. Cl. 362/147; 174/254; 439/444; 439/436

(57) ABSTRACT

A wallpaper (1) for contacting an electrical device (2), which is attachable to a wall (3), preferably attachable to any kind of room walls or ceiling or flooring of a building, whereas the wallpaper (1) comprises a plurality of conductive stripes (4), and whereas the electrical device (2) features contact pins (5) in order to contact the conductive stripes (4), characterised in that the conductive stripes (4) feature a certain stripe pitch (6) and the pins (5) feature a certain pin pitch (7), whereas different conductive stripes (4) feature different voltages in order to match the contact voltage of the contact pins (5) due to the contacting of different conductive stripes (4) basing on the certain pitches (6, 7) by placing the electrical device (2) in different positions.

The present invention relates to a wallpaper for contacting an electrical device, which is attachable to a wall, preferably attachable to any kind of room walls or ceiling or flooring of a building, whereas the wallpaper comprises a plurality of conductive stripes, and whereas the electrical device features contact pins in order to contact the conductive stripes.

To contact electrical devices, which are applied on walls for lightning, illuminating rooms or contacting electrical devices, which are used as lamps, markers or signal devices, feature a contacting, which is usually performed by conventional wiring. The wiring is arranged underneath the wallpaper or insight a recess, which is formed inside the wall material. Unfortunately, it is not possible to change the position of the electrical device on the wall, because the changing of the position of the wiring would lead to a high effort. In particular in modem rooms a flexible lightning is desirable, what means, that the electrical device, which can be performed as a conventional lamp or a semiconductor device like LED or an OLED may be changed within one single wall or between the ceiling and the wall. If the electrical device is performed as a marker or a signal device, it is desirable similar to the flexible lightning, whereas the markers may be performed as illuminating panels, basing on OLEDs.

Different electrical contact systems are already existing which are basing on a plurality of conductive stripes being arranged underneath the wallpaper, and which are invisible and which may be contacted by sticking the electrical device onto the wall, which comprises contact pins, and feature a piercing through the wallpaper into the electrical conductive stripes for contacting them. The stripes are arranged in a parallel formation on the surface of the wall, in order to perform an easy contacting of the electrical device.

The document FR 2496350 discloses a sheath of electrical conductors allowing an instantaneous connection over its entire length of any electrical or electronic apparatus, in a visible or invisible fashion, whereas it is composed of two sheets of PVC or other suitable material sandwiching the conductive elements constituting a passage in which a plug will be introduced. It can be fixed to a partition by bonding, by applying an adhesive material or other fixing devices. Thus, it is possible to implement the electrical device on any support in any structure. The sheath leads to a protection to avoid an electric shock to an user. The conductive stripes are arranged in certain distances to each other, whereas the blades for contacting the plug of the electrical device feature the same distance like the conductive stripes. Thus, it is possible to contact the blades of the plug, which may be applied at any place within the wall.

The WO 99/28917 discloses a surfaces mounted, flexible, multi-purpose wire, which comprises a plurality of flat elongated conductive stripes, spaced apart in a generally parallel relationship, wherein each of said plurality of flat conductors comprises a plurality of aluminum layers, and wherein said conductors have high and low voltage and current carrying capacity, and whereas an insulating layer is surrounding and separating said plurality of flat conductors, wherein a cross-section height of said flat conductors and the insulation layers is less than 0.04 inches.

Another electrical contact system is disclosed in the document U.S. Pat. No. 6,132,859. This system relates to a sandwich panel with conductive cores interposed between layers of form insulating material, particularly of polyurethane, supporting elements provided with at least one pin for collection to the cores, particularly lamps, supplied with electrical energy by these cores connected to a source of current, whereas the insulating foam material has an elasticity threshold at least equal to the maximum pressure exerted by one of the pins of an element inserted in the foam. In this electrical contact system the voltage carrying layers are arranged on top of each other, whereas the construction of the pin for contacting the different layers is very complex, because it is similar to a stereo jag of an audio system. Another disadvantage is the plain and laminar arrangement of the layers, which leads to the same voltage across the whole surface.

Another electrical device basing on piercing by pins is described in the document U.S. Pat. No. 4,888,232. It is disclosed an electrically conductive layer board for use with low-voltage electrical equipment provided with piercing connectors, preferably for display proposals, comprising at least one first thin metal foil, preferably aluminum applied to an electrically insulating layer, the insulating layer including a plastic material that is sufficiently pliable to allow the metal foil to be deformed and bent into said insulating layer, when a connector is pressed through the metal foil into, and to be held by, the insulating layer thus ensuring a large contact surface between said connector and said metal foil. The principal of connecting the conductive layers is basing on a specific design of the pin, which may be associated with light emitting diodes. The pin comprises a first and a second electrical contact loop, being axially arranged in relation to each other and being separated by an insulating layer or a part of it. Thus, this principal features the same disadvantage of matching the same voltage height across the whole surface of the layers. Different voltage heights only can be achieved by different depths, in which the pins may be pierced into. Therefore, it is not possible to provide different voltages to the electrical device, while the device is arranged in different positions across the wall, on which the layers are applied.

The invention has the objective to eliminate the above mentioned disadvantages. In particular it is an objective of the present invention to provide a wallpaper for contacting an electrical device, which may be provided by different voltage heights, while the electrical device is applied at different positions in one wall.

The objective is achieved by a wallpaper as taught by claim 1 of the present invention. Preferred embodiments of the invention are defined in the subclaims. Also, the objective is achieved by an electrical device as taught by the claim 7. Advantage embodiments of the inventive device are defined in the subclaims.

The invention discloses, that the wallpaper comprises conductive stripes featuring a certain stripe pitch and the pins featuring a certain pin pitch, whereas different conductive stripes feature different voltages in order to match the contact voltage of the contact pins due to the contacting of different conductive stripes basing on the certain pitches by placing the electrical device in different positions.

By placing the stripes and the pins in certain pitches, a match can be made in such a way, that two pins always contact two different stripes, whereas a short cutting is avoided. If the electrical device is placed on a first position, two pins may contact to certain stripes, whereas each stripe feature a certain voltage height. When the electrical device is moved to a next position, which relates to a distance corresponding to the pitch of the stripes, another voltage height can be provided to the electrical device. Thus, it is possible to change the applied electrical voltage height, while the electrical device only needs to be repositioned, which may happen stepwise. Depending on the kind of the electrical device, effects like emitted colors, the brightness or intensity of the light emitting or other effects may be achievable.

According to another embodiment of the present invention the conductive stripes of the wallpaper are sandwiched between the wall and wallpaper in order to provide an electrical insulation of the conductive stripes. The wallpaper may be a usual wallpaper or any kind of tapestry, which may cover the conductive stripes, whereas the appearance of the wall, which may be e.g. a wall in a living room of a building, appears in a general known way and the contact system is invisible. Thus, the stripes are invisible arranged behind the wallpaper and the stripes do not appear and can not be touched by a user. Therewith the wallpaper comprises the function of insulation against an electric shock. When the electrical device is stucked onto the wall, the pins extend to the wallpaper and the conductive stripes, respectively, what means, that the pins feature a length, to pass through the wallpaper.

In another embodiment of the present invention the conductive stripes, which are arranged adjacent to each other, feature voltage levels, which are selected from certain steps. The voltage levels of the conductive stripes may feature a step wide of 3V from stripe to stripe, whereas the stripes may feature 0V, 3V, 6V, 9V or 12V in a subsequent order. Regarding the voltage height different voltages are feasible, which feature lower or higher increments, and which feature a voltage height, which is higher than 12V. According to these voltage steps, five different circuits within the wallpaper are applied, whereas the stripes with the different voltages are arranged in a neighboring manner, whereas the voltage height repeats in a five-step-manner. If an electrical device like an OLED-device is stucked onto the wall, the pins for the electrical contacting feature an unchangeable pitch. If the device is stucked on, the pitch may comprise a distance, which overlaps through the distance of three stripes. If the necessary supply voltage relates to 6V, and the voltage difference between two neighboring stripes is 3V, the distance of the pin pitch may comprise two stripe pitches. If each neighboring stripe features a voltage difference of three volts, two pitches of the stripes lead to six volts, which may match the necessary supply voltage of the OLED-device. For example, if the device comprises two pins, and the first pin contacts the conductive stripe comprising 9V, and the second pin contacts the conductive stripe, featuring 3V, the resulting supply voltage to the OLED-device is 9V−3V=6V. Or, if the first pin contacts 6V and the second pin contacts 0V, also the resulting cross-voltage leads to 6V. This principal of the bridging of certain voltage distances is applicable between each conductive stripe, featuring 0V, 3V, 6V, 9V, 12V or different voltages.

Usually a plurality of wallpapers is sticked to a wall, which consist of lanes with a certain width, and are arranged adjacent to each other. In order to realize a certain contacting of the electrical devices with a certain stripe pitch of different wallpaper lanes it can be necessary to arrange a through-contacting of the stripes or a defined control of the voltage levels in the neighbouring conductive stripes of different wallpaper lanes. This can be carried out by a central voltage control unit, which is applied for the voltage supply of at least one entire wall.

In terms of the material of the conductive stripes the material is selected from the group of metallic conductive material, comprising copper material, aluminum, silver, gold or steel material. The material properties show a high electric conductivity in order to minimize the lost of electric power. Within a large wall, the conductive stripes show an extensive length and the electrical feeding of an external electrical supply only happens in one point, preferably at the floor edge or any other edge of the wall, where the electrical feeding into the stripes may be invisible.

According to another embodiment of the present invention the conjunction of the conductive stripes onto the wall and/or the wallpaper onto the conductive stripes is performed by gluing. A first possibility is gluing the stripes onto the wall, and subsequently gluing the wallpaper onto the stripes. An alternative possibility may be to produce a wallpaper, where the conductive stripes are already brought in, what means, that the wallpaper already comprises the stripes and only has to be glued onto the wall.

Furthermore the invention relates to an electrical device, which is attachable to a wall, whereas a wallpaper is arranged on the wall and comprises a plurality of conductive stripes, arranged in a parallel formation to each other and featuring a certain stripe pitch, whereas the electrical device features at least two contact pins for contacting the conductive stripes, wherein the pins of the electrical device feature a certain pin pitch, whereas different conductive stripes feature different voltages in order to match the contact voltage of the contact pins due to the contacting of different conductive stripes basing on the certain pitches by placing the electrical device in different positions.

Preferably, the electrical device comprises an organic light emitting diode (OLED), whereby the OLED may be used as a marker and/or illuminator of the corresponding room of the building, where the OLED is applied. An organic light emitting diode (OLED) features a thin film, which is performed as a kind of a light emitting diode, in which the emissive layer is an organic compound. OLED-technology is feasible as practical display devices. Thus, it is possible to use OLED-displays on the wall of a room, whereas the position of the display may be changed. The thickness of OLED-emitters is quite small (less than 1 mm), whereas the OLED itself may be received in a frame-like body, whereas the pins for the electrical contacting are arranged in the frame-like body. OLED-devices are performed as thin foils, which are quite flexible, and which may feature a size of 5×5 cm or up to 12×12 cm or more. Different OLED-sizes need different voltage supply, which means, that the supplied voltage being necessary can be matched by a certain pin pitch in order to ensure, that the OLED is supplied by the correct voltage in dependence on the size of the OLED device.

Different electrical devices may be power supplied by an electrical contact system according to the present invention, which regard to LEDs, OLEDs, electroluminescent panels, lamps, wall watches, thermometer, multimedia systems, video projectors, television systems, control units e.g. for heating installations for buildings, systems of data networks etc. In the first instance the maximal voltage level is not limited, but against the background of the risk of electrical shocks for users the maximal voltage level is limited by approximately 50 . . . 60V, advantageously. The electrical current can comprise a direct current (DC) or an alternating current (AC), or the electrical system is supplied by electrical signals, which are pulsed, switched or modulated in any different way.

According to another embodiment of the invention the contact pins are arranged on one face of the electrical device, whereas the face comprising the pins abuts to the wall and the wallpaper, respectively. Advantageously, the pins comprise at least two pins for an usual electrical connection, whereas the pins may be arranged in a horizontally or a vertically direction, whereas the pins also may be arranged in any different angles to each other. Preferably, the electrical device is stucked on in a horizontally or vertically direction, but even a tilted position is possible, when the pins are arranged in a diagonal line. The pins may be received or arranged on the frame-like body providing an inherently stable chassis in order to save the functionality of the device.

Advantageously, the electrical device comprises a double-side adhesive foam in order to be stickable onto the wall and the wallpaper, respectively. The double-side adhesive foam can be provided as a foam as itself, or as an adhesive tape, a sticky tape or a glue-like compound. The sticky principle has to be tight enough to keep the electrical device on the wall, and to insure a reliable contact of the pins to the conductive stripes. Alternatively, a mechanical connection principle can be applied, which concern a fastening by nails or screws. In the case, that no adhesive compound is used, it is possible, that the mechanical fastening of the electrical device is realized by piercing in the pins into the wallpaper and the conductive stripes, respectively, like a pushpin.

According to another embodiment of the present invention the pins are performed as sharpened needle-like pins in order to pierce through the conductive stripes by applying the electrical device on the wall. By sharpening the pins at their end, the pins and thus the electrical device may be stucked easier to the wall, whereas the pins achieve a nail function. The piercing-effect is supported by the sharpened ends of the pins, what means, that less pressing force is necessary to drive the pins through the wallpaper and in particular through the metallic conductive stripes. Preferably, the metallic conductive stripes comprise a smooth and tender deformation behavior, and feature a low thickness, which leads to a high flexibility of the stripes and the pins are able to be impressed into or pressed through the stripes. Ensuring a save electrical contacting, the pins should pass the stripes, whereas an impressing into the surface of the stripes may be sufficient, but not necessarily effectual. If the pins are grooved, they may achieve a fastening effect, what means that further fastening means are not necessary and the electrical device is fastened to the wall only by impressing the prints into the stripes.

Alternatively to sharpened needle-like pins the pins may be spring loaded in order to be pressed onto the surface of the conductive stripes. The pressing force, which is applied to the pins for pressing the pins onto the conductive stripes, is accumulated within the springs, because the springs can be compressed by sticking the electrical device onto the wall and thus, impressing the pins against the springs. This ensures a reliable contacting of the conductive stripes, while it has to be insured, that the wallpaper or tapestry is already cut through by the pins to avoid an insulation effect of the wallpaper between the pins and the stripes. According to this contacting principle the device may not be fixed to the wall only by impressing the pins, what means, that additional fastening means are necessary. The advantage of this principle is a reliable contacting, when the conductive stripes show corrosion-effects, and the spring force presses the pins onto the surface of the stripes, continuously.

Also, the present invention relates to an electrical contact system according to claim 13, wherein the wallpaper comprises conductive stripes and the electrical device comprises at least two contact pins, which are arranged to contact the conductive stripes in order to power supply the electrical device by a current in the conductive stripes.

Additional details, characteristics and advantages of the objective of the invention are disclosed in the subclaims and the following description of the respective figures—which are an exemplary fashion—show preferred embodiments of the invention, which will be described in conjunction with the accompanying figures, in which:

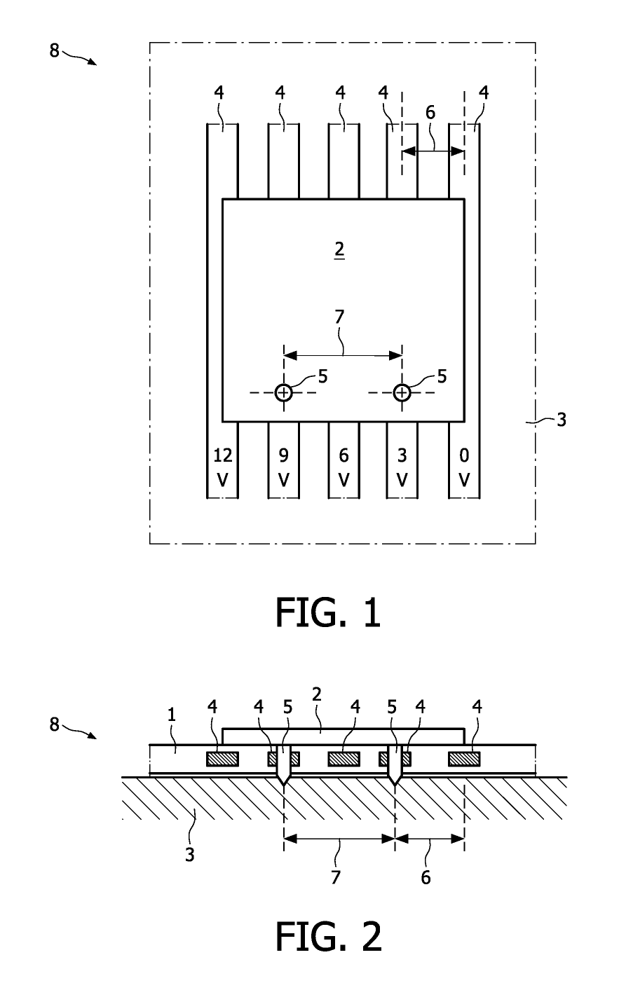

FIG. 1 shows the arrangement of an electrical contact system in a plan view, whereas the wallpaper is removed; and

FIG. 2 shows a side view of the arrangement of the electrical contact system according to FIG. 1, whereas the wall and the wallpaper are cross-sectioned.

The electrical contact system 8 shown in FIG. 1 comprises an electrical device 2, which is simplified shown as an oblong box. The electrical device 2 is positioned on the top layer, whereas the wall 3 is arranged at the bottom layer. Between the electrical device 2 and the wall 3 a plurality of conductive stripes 4 is arranged. The conductive stripes 4 are disposed parallel together in a lengthwise direction, and comprise a certain distance between each other. The conductive stripes 4 extend across the whole wall 3, and are cut in lengthwise direction for depiction in FIG. 1. Exemplarily, five conductive stripes 4 are shown, which feature different voltage levels. Likewise exemplarily, the voltage levels 0V, 3V, 6V, 9V and 12V are written on the conductive stripes 4, whereas adjacent to the package of five conductive stripes 4 the voltage levels may be repeated. Thus, the conductive stripes 4 across the whole wall 3 feature a periodic repetition of these five voltage levels. The conductive stripes 4 are arranged in a certain stripe pitch 6, which describes the lateral distance between one stripe 4 to the next neighboring stripe 4. The stripe pitch 6 is repeated between each conductive stripe 4, whereas the pitch 6 between the different voltage levels, represented by different stripes 4 can also be different, whereas across the whole wall 3 the lateral stripe pitch 6 may only be equal between certain voltage levels.

The electrical device 2 features two pins 5, which comprise a certain pin pitch 7. The pin pitch 7 is matched to the certain stripe pitch 6 in order to contact certain conductive stripes and to grip a certain potential between certain stripes 4. According to the embodiment in FIG. 1 the conductive stripe 4 featuring 3V and the conductive stripe 4 featuring 9V are contacted by the pins 5. This leads to a cross voltage of 6V, whereas if the pins 5 feature another pin pitch 7, e.g. different voltage levels like 3V or 9V or 12V are visible. Even though it is not shown in FIG. 1, the stripe pitch 6 may feature variable values between different voltages in order to contact different voltage potentials by the pins 5, while the electrical device 2 is stucked on another position on the wall 3. The wallpaper is not shown in FIG. 1 in order to uncover the conductive stripes 4. The pins 5 are pressed into the conductive stripes 4 and the electrical device 2 is stucked onto the wallpaper (not shown), e.g. by a double side foam with an adhesive effect.

FIG. 2 shows the embodiment of the present invention according to FIG. 1, whereas the electrical contact system 8 is cross sectioned. On the bottom side the wall 3 is shown in a cross sectioned view, whereas the stripes 4 are arranged onto the wall 3. Five stripes 4 are shown, which are also cross sectioned. Between the electrical device 2 and the conductive stripes 4 a wallpaper 1 is disposed, whereas the wallpaper 1 comprises conductive stripes 4, what means, that the conductive stripes 4 are surrounded by the wallpaper 1 in order to provide the wallpaper 1 comprising the conductive stripes 4 as a single compound. The stripes 4 feature a stripe pitch 6, which describes the lateral distance between the stripes 4. The pins 5 contact the conductive stripes 4, while the pins 5 are arranged on the bottom side of the electrical device 2 and pass through the wallpaper 1 into two conductive stripes 4. By applying this piercing principle of the pins 5 into the conductive stripes 4 the electrical contacting is realized in order to contact the electrical device 2 with the electrical voltage supplied by the conductive stripes 4. The electrical device 2 can be embodied as an OLED-device emitting light to the top side of the OLED-device in the opposite direction of the wall 3. The OLED-device may be received within a frame-like compound, which is not shown in FIG. 2.

The present invention is not limited by the embodiment described above, which is represented as an example only and can be modified in various ways within the scope of protection defined by the appended patent claims. Thus, the invention is also applicable to different embodiments, in particular of the design of the OLED-device and/or the structure of the wallpaper 1.

### LIST OF NUMERALS

1 wallpaper
2 electrical device
3 wall
4 conductive stripe
5 contact pin
6 stripe pitch
7 pin pitch
8 contact system

1. A wallpaper for contacting an organic light emitting diode comprising one or more contact pins having a predetermined pin pitch and attachable to a wall, the wallpaper comprising a plurality of conductive stripes having a predetermined stripe pitch wherein at least some of the conductive stripes feature different voltages in order to match the contact voltage of the contact pins due to contacting of different conductive stripes depending on positioning of the organic light emitting diode.

2. The wallpaper of claim 1, wherein the conductive stripes are sandwiched between the wall and the wallpaper for providing an electrical insulation of the conductive stripes.

3. The wallpaper of claim 1, wherein the conductive stripes feature discrete voltage levels.

4. The wallpaper of claim 3, wherein the voltage levels of the conductive stripes are divisible by 1.

5. The wallpaper of claim 1, wherein the conductive stripes comprise a metallic conductive material selected from the group consisting of: copper, aluminium, silver, gold and steel.

6. (canceled)

7. A lighting system comprising (i) an electrical device attachable to a wall, the electrical device comprising organic light emitting diode comprising one or more contact pins having a predetermined pin pitch, and (ii) a wallpaper arranged on the wall and comprising a plurality of conductive stripes, arranged in a parallel formation relative to each other, the conductive stripes having a predetermined stripe pitch, wherein at least some of the conductive stripes feature different voltages in order to match the contact voltage of the contact pins due to contacting of different conductive stripes depending on positioning of the electrical device.

8. (canceled)

9. The lighting system of claim 7, wherein the contact pins are arranged on a face of the electrical device abutting the wall.

10. The lighting system of claim 7 wherein the electrical device further comprises a double-side adhesive foam.

11. The lighting system of claim 7 wherein the pins sharpened ends for piercing through the conductive stripes when the electrical device is being attached to the wall.

12. The lighting system of 7 wherein the pins are spring loaded in order to be pressed onto the surface of the conductive stripes.

13. (canceled)

14. The wallpaper of claim 3, wherein the voltage levels of the conductive stripes are divisible by 2.

15. The wallpaper of claim 3, wherein the voltage levels of the conductive stripes are divisible by 3.

16. The wallpaper of claim 3, wherein the voltage levels of the conductive stripes are divisible by 6.
